(19) United States
(12) Patent Application Publication
(10) Pub. No.: US 2020/0168646 A1
(43) Pub. Date: May 28, 2020

(54) INTEGRATED IMAGING DEVICE WITH AN IMPROVED CHARGE STORAGE CAPACITY

(71) Applicant: STMicroelectronics (Crolles 2) SAS, Crolles (FR)

(72) Inventors: Andrej SULER, Grenoble (FR); Francois ROY, Seyssin (FR)

(73) Assignee: STMicroelectronics (Crolles 2) SAS, Crolles (FR)

(21) Appl. No.: 16/681,161

(22) Filed: Nov. 12, 2019

(30) Foreign Application Priority Data
Nov. 22, 2018 (FR) 1871689

(51) Int. Cl. H01L 27/146; H01L 49/02

(52) U.S. Cl. CPC H01L 27/14603; H01L 28/60; H01L 27/14636; H01L 27/14614

(57) ABSTRACT

An integrated imaging device includes a pixel having a trench that extends into the substrate. The trench is coated with an insulator and filled with a stack including a first polysilicon region and a second polysilicon region. The first and second polysilicon regions are separated from each other by a layer of insulating material. The first polysilicon region may form a gate electrode of a vertical transistor and the second polysilicon region may form an electrode of a capacitor.

### PRIORITY CLAIM

This application claims the priority benefit of French Application for Patent No. 1871689, filed on Nov. 22, 2018, the content of which is hereby incorporated by reference in its entirety to the maximum extent allowable by law.

### TECHNICAL FIELD

Embodiments relate to integrated circuits, especially imaging integrated circuits, and in particular to the improvement of the dynamic range of imaging devices.

### BACKGROUND

An imaging device conventionally comprises a matrix array of pixels operable to convert an incident light signal into electrical charge. In each pixel, the charge generated in a photosensitive zone, conventionally a photodiode, is transferred to a read node that is coupled to a transfer circuit and to a processing circuit, for example, comprising an analog-to-digital converter operable to convert the electrical charge representative of the illumination of the pixel into a digital value.

The value of the illumination of a pixel may take a number of values dependent on the dynamic range of the imaging device, i.e., the ability of the imaging device to distinguish between a greater or lesser number of light intensities.

It is possible to increase the dynamic range of an imaging device by combining a plurality of captured images. However, the image sensors allowing such methods to be implemented comprise specific and often complex circuits, to the detriment of the footprint of the integrated circuit.

There is a need to obtain an imaging device of high dynamic range having a small footprint.

### SUMMARY

According to one embodiment, an imaging device is proposed that allows high-dynamic-range images to be produced, wherein the pixels have a small footprint.

According to one aspect, an integrated imaging device is provided comprising at least one pixel comprising at least one trench extending into the substrate, said at least one trench being coated with an insulator and comprising a stack of a lower first polysilicon region and of at least one upper second polysilicon region, which regions are separated by a layer of said insulator.

The production of two polysilicon regions in the interior of the same trench is therefore particularly advantageous in the case of a pixel, because it for example allows, within the same trench, two separate elements having two separate functions (for example a buried transfer gate and a capacitor or indeed a peripheral isolation region and a capacitor) to be produced with a small footprint.

This being so, more generally, such a trench may advantageously be incorporated in any integrated circuit or device.

Specifically, in this case production of two polysilicon regions in the interior of the same trench is particularly advantageous because it, for example, allows two separate capacitive components to be produced with a small footprint.

Thus, according to another more general aspect, an integrated circuit or device is provided that comprises at least one trench extending into the substrate, said at least one trench being coated with an insulator and comprising a stack of a lower first polysilicon region and of at least one upper second polysilicon region, which regions are separated by a layer of said insulator.

Whatever the envisioned application, the first polysilicon region produced more deeply in the substrate is advantageously insulated from the components produced on the front side of the substrate.

This is, for example, the case, as will be described below, when the first polysilicon region forms a transfer gate of a pixel, this transfer gate then being insulated from the read node of the pixel, which is implanted at small depth in the substrate.

In the case of an integrated imaging device, the pixel may comprise a capacitor a first electrode of which comprises the second polysilicon region, the dielectric of which is formed by the insulator, and the second electrode of which is coupled to a storage region, for example a read node, configured to store charge representative of an illumination of the pixel, the pixel furthermore comprising a biasing circuit operable to separately bias the first polysilicon region and the second polysilicon region.

Coupling a capacitor to a charge storage region advantageously allows the storage capacity of said region to be increased by biasing the second polysilicon region to an appropriate value.

As a variant, it would be possible to make provision for the pixel to comprise a metallization connecting the second polysilicon region and said storage region.

This allows the capacity of the storage region (read node) to be increased without there being any need to use the aforementioned biasing circuit.

Said stack may be surmounted by a region of insulator.

Adjusting the proportion of polysilicon and of insulator in the stack allows the size of the two polysilicon regions to be adjusted and therefore the capacitive effect of the capacitor to be adjusted.

In a first variant embodiment, the transfer gate of the pixel and the capacitor are located in said trench.

More precisely, the pixel may comprise a photosensitive zone, a read node comprising said storage region, at least one transfer gate operable to transfer said charge accumulated in the photosensitive zone to the read node, said at least one trench delineating the periphery of the read node, the first polysilicon region forming the transfer gate, the second polysilicon region forming a first electrode of the capacitor and the read node forming a second electrode of the capacitor.

Production of the capacitor and of the transfer gate in the same trench advantageously allows the storage capacity of the read node to be increased while maintaining a small footprint.

According to another variant embodiment, said at least one trench may form a capacitive isolation trench delineating the periphery of the pixel, said second polysilicon region forming a first electrode of the capacitor and the second electrode of the capacitor being connected to the read node by way of metal tracks.

According to another aspect, a smart mobile telephone comprising an imaging device such as described above is proposed.

According to one aspect, a digital camera comprising an imaging device such as described above is proposed.

### BRIEF DESCRIPTION OF THE DRAWINGS

Other advantages and features will become apparent on examining the detailed description of completely non-limiting embodiments and the appended drawings, in which:

FIG. 1 is a schematic representation from an electrical point of view of a pixel of one embodiment of an imaging device;

FIG. 2 is a view from above of the pixel of FIG. 1;

FIG. 3 is a cross-sectional view along the section line III-III of FIG. 2;

FIG. 4 is a cross-sectional view along the section line IV-IV of FIG. 2;

FIG. 5 illustrates a variant embodiment;

FIG. 6 illustrates a variant embodiment;

FIG. 7 illustrates a variant embodiment;

FIG. 8 illustrates another aspect;

FIG. 9 illustrates another aspect; and

FIG. 10 illustrates another variant.

### DETAILED DESCRIPTION

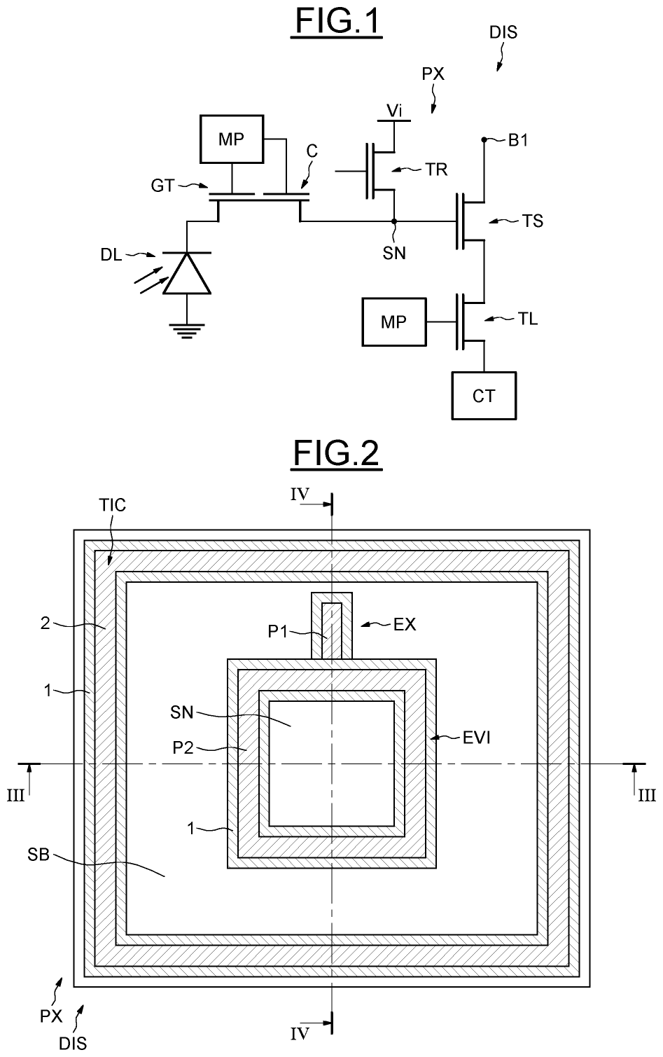

FIG. 1 is a schematic representation from an electrical point of view of a pixel PX of an imaging device DIS.

Although the imaging device DIS comprises a matrix array of pixels, each of the pixels has an identical architecture and an identical operating mode. A single pixel will therefore be described for the sake of simplicity.

The pixel PX conventionally comprises a photosensitive zone DL, here a photodiode, operable to generate electrical charge in response to an illumination of the pixel PX, a read node SN and a transfer gate GT configured, when it is switched on, to transfer charge from the photodiode DL to the read node SN.

The read node SN is conventionally operable to receive the charge generated by the photodiode DL in order to read the charge and convert said charge into a digital value representative of the illumination of the pixel PX.

This readout is performed by way of a source-follower transistor TS the gate of which is coupled to the read node SN and by way of a read transistor TL, where the transistors TS and TL are coupled in series between a supply terminal B1 operable to deliver a first voltage, for example a voltage of 3 volts, and a processing circuit CT operable to carry out operations on the electrical signal coming from the pixel PX, in particular an analog-to-digital conversion.

The pixel PX further comprises an initialization transistor TR, also referred to as a reset transistor, operable to initialize the electrical potential of the read node SN to an initialization value Vi.

The pixel PX further comprises a capacitor C having a first electrode that is coupled to a biasing circuit MP and a second electrode that comprises the read node SN.

This capacitor CS advantageously allows the charge storage capacity of the read node to be increased.

In operation, during an illumination of the pixel PX, electric charge carriers, electrons and holes, are accumulated in the photosensitive zone DL and the biasing circuit MP biases the transfer gate GT to a first value, for example here −0.5 volts, and the first electrode of the capacitor C to a second value, for example here 3 volts. This configuration of the biasing circuit MP makes it possible to prevent charge from accumulating on the read node during the illumination of the pixel.

The biasing circuit MP then biases the transfer gate GT and the first electrode of the capacitor C to the second value, here 3 volts, in order to transfer the electrons accumulated in the photosensitive zone DL to the read node SN.

In order to read and process the charge accumulated on the read node, the biasing circuit MP biases the gate of the read transistor TL in order to turn transistor TL on.

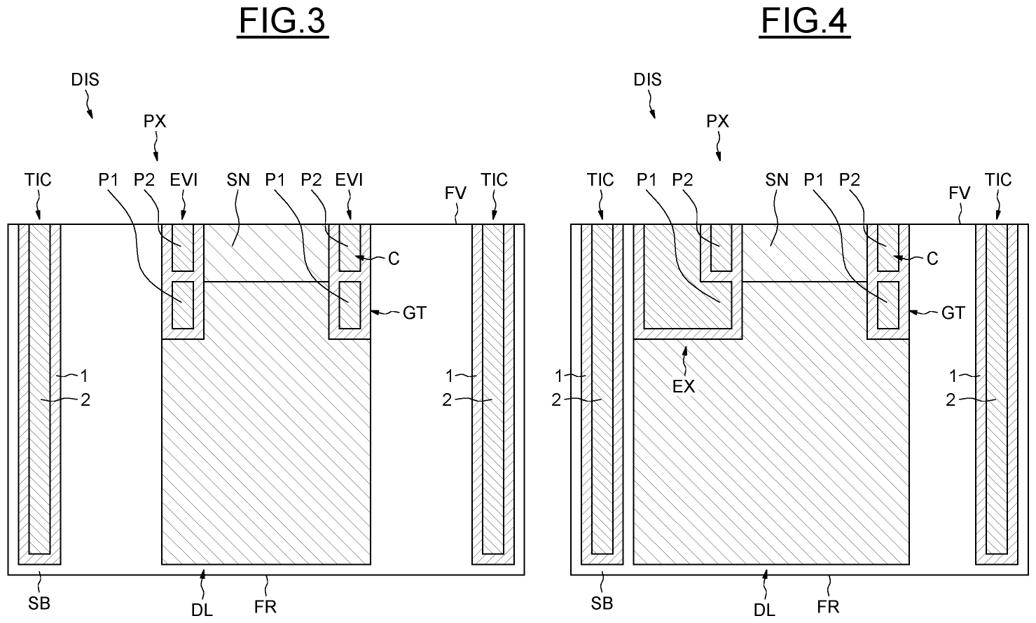

FIG. 2 is a view from above of the pixel PX, and FIG. 3 is a cross-sectional view along the section line III-III in FIG. 2, and FIG. 4 is a cross-sectional view along the section line IV-IV in FIG. 2.

The imaging device DIS is here a back-side illuminated (BSI) device, i.e., the device is operable to be illuminated from the back side FR of the substrate SB. The front side FV is for its part surmounted by a back-end-of-line (BEOL) interconnect portion, which is not shown in the figures for the sake of simplicity.

For the sake of simplicity, only the transfer node SN, the transfer gate GT and the photosensitive zone DL have been shown in FIGS. 2 to 4.

The device DIS is produced in a semiconductor substrate SB, for example here a silicon substrate having a p-type conductivity, and the pixel PX is delineated by a capacitive isolation trench TIC extending all around the periphery of the pixel.

The capacitive isolation trench TIC is conventionally a trench produced in the substrate and extending from its front side FV to a depth of about 3.5 microns, this trench being coated with an insulator 1, for example here silicon oxide, and filled with a conductor 2, here polysilicon.

The photosensitive zone DL is here produced by implanting n-type dopants extending from the front side to a depth of 3 microns for example.

The pixel PX further comprises an insulated vertical electrode EVI delineating the periphery of the read node SN, which itself is a region doped n-type, the latter being more strongly doped than the photosensitive zone and extending into the substrate SB to a depth of about 0.3 microns.

The insulated vertical electrode EVI is a trench produced in the substrate SB and extending from its front side FV to a depth of about 0.8 microns, this trench being coated with the insulator 1.

The vertical electrode EVI is filled with a stack of a first polysilicon region P1 and of a second polysilicon region P2, the first polysilicon region P1 and the second polysilicon region P2 being separated by a layer of insulator 1.

The second polysilicon region P2 extends from the front side FV of the substrate SB to a depth of about 0.3 microns in the substrate SB, i.e., to the same depth as the read node SN.

The first polysilicon region P1 extends under the second polysilicon region P2 as far as to the bottom of the vertical electrode EVI, i.e., here to a depth of about 0.8 microns.

The transfer gate GT comprises the first polysilicon region P1. The first electrode of the capacitor C comprises the second polysilicon region P2, and the second electrode of the capacitor comprises the read node SN.

The insulated vertical electrode further comprises an extension EX extending away from the read node and allowing contact to be made with the first polysilicon region.

Thus, the transfer gate GT is sufficiently far from the read node SN to avoid parasitic capacitive coupling between the read gate GT and the read node SN during the transfer of charge from the photosensitive zone DL to the read node SN, and biasing the capacitor C allows the storage capacity of the read node SN to be increased via a capacitive effect.

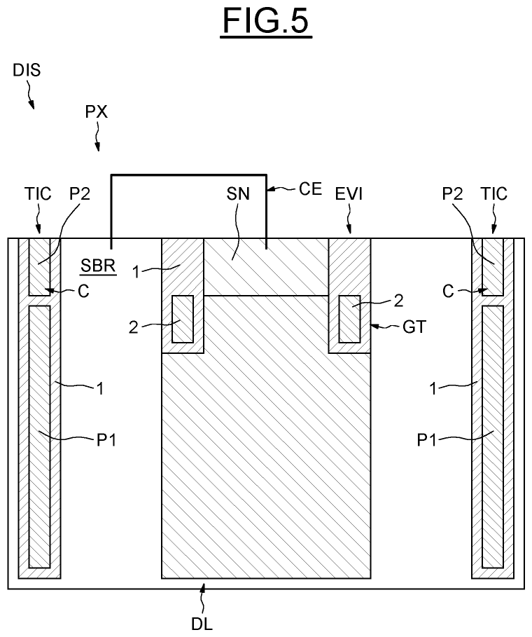

According to one variant embodiment illustrated in FIG. 5, the capacitor C is produced in the capacitive isolation trench TIC.

Thus, the capacitive isolation trench TIC is filled with a stack of a first polysilicon region P1 and of a second polysilicon region P2, the first polysilicon region and the second polysilicon region being separated by a layer of the insulator 1.

Here again, one electrode of the capacitor C is formed by the second polysilicon region P2 and the other electrode by the substrate region SBR adjacent to the trench.

An electrical connection CE is here produced between the read node SN and the substrate region SBR. The electrical connection CE schematically shown in FIG. 5 is in practice produced by way of vias and metal tracks from the BEOL structure of the interconnect region of the device DIS.

Thus, in this embodiment, the storage node is also coupled to the capacitor C.

The insulated vertical electrode EVI here comprises a stack of a lower polysilicon region forming the transfer gate GT and of an upper region of insulator 1 extending from the front side of the substrate to a depth of about 0.3 microns, i.e., to a depth about equal to that of the read node SN, advantageously allowing the distance between the transfer gate GT and the read node SN to be increased and therefore this gate to be electrically isolated from this node.

It would also be possible for the vertical electrode to have the same structure as that described above with reference to FIGS. 1 to 4, these two embodiments being compatible.

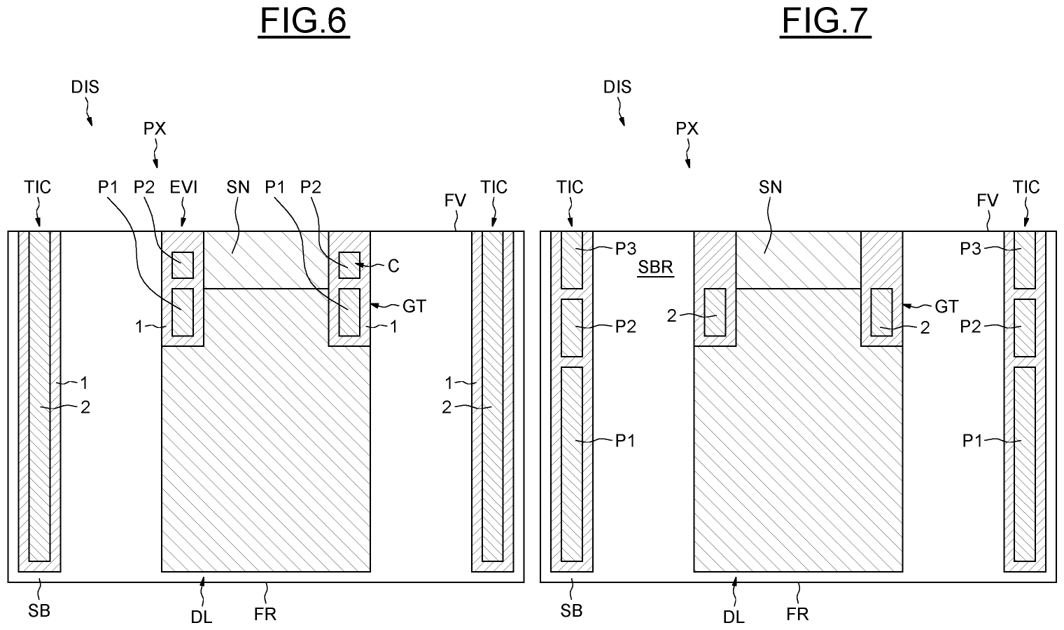

According to one variant embodiment illustrated in FIG. 6, it would be possible for the stack of the first polysilicon region P1 and of the second polysilicon region P2 to be surmounted by a layer of the insulator 1, replacing one portion of the second polysilicon region P2, which is therefore here smaller than in the other embodiments. Adjusting the size of the second electrode of the capacitor C is one advantageous means of adjusting the storage capacity of the read node SN.

It would further be possible, as illustrated in FIG. 7, for the capacitive isolation trench TIC to comprise more than two polysilicon regions, for example here 3 regions P1, P2 and P3. This advantageously allows the capacitance of the read node to be adjusted during the operation of the device DIS by, for example, biasing only the second region P2 or indeed both the second region P2 and the third region P3.

The architecture of the pixel described here corresponds to an architecture of a so-called rolling shutter imaging device. It would however be perfectly possible to integrate the embodiments into any other pixel architecture, in particular into a so-called global shutter pixel architecture. This type of image sensor comprises, for each pixel, in addition to the read node SN, a storage node allowing the charge representative of the illumination of the pixel to be temporarily stored. In this case, the storage node would also be coupled to a capacitor analogous to the capacitor C described above.

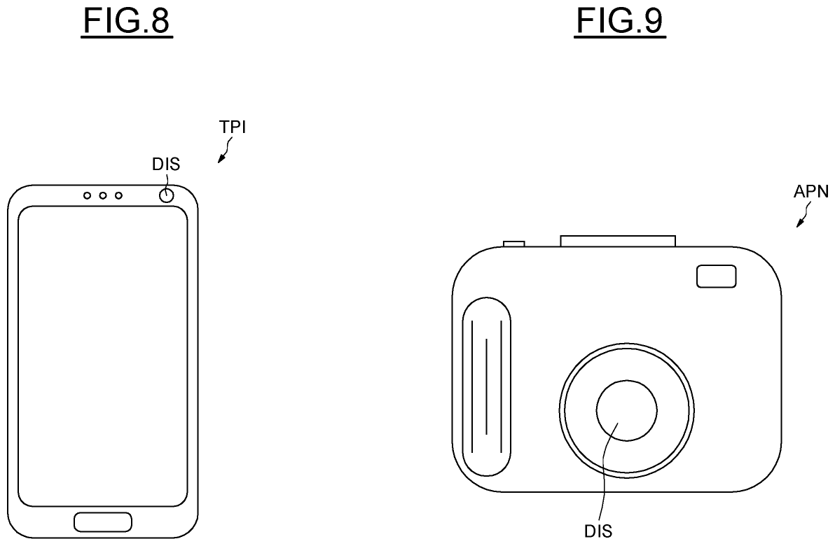

The imaging device DIS described above and illustrated in FIGS. 1 to 7 may be integrated into any type of imaging system, such as for example a smart mobile telephone TPI such as that illustrated in FIG. 8, or a digital camera APN such as that illustrated in FIG. 9.

The invention is not limited to the embodiments that have just been described but encompasses any variant thereof.

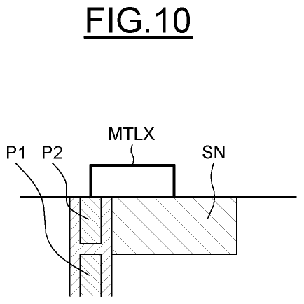

Thus, it would be possible, in order to increase the capacity of the read node SN, to do away with the biasing means MP (able to separately bias the first polysilicon region P1 and the second polysilicon region P2) and to make provision for a metallization (metal track) connecting the read node SN and the second polysilicon region P2, as very schematically illustrated in FIG. 10.

1. An integrated imaging device, comprising:
at least one pixel which comprises:
a trench extending into the substrate;
an insulator coating said trench;
a stack within said trench including a first polysilicon region and a second polysilicon region, wherein the first and second polysilicon regions within the stack are insulated from each other by a layer of insulating material; and
a capacitor having a first electrode formed by the second polysilicon region, a dielectric formed by the layer of insulating material, and a second electrode coupled to a storage region which is configured to store charge representative of an illumination of the at least one pixel.

2. The device according to claim 1, wherein the at least one pixel further comprises a photosensitive zone, a read node comprising said storage region, and at least one transfer gate configured to transfer said charge accumulated in the photosensitive zone to the read node, wherein said trench delineates a periphery of the read node, with the first polysilicon region forming the transfer gate.

3. The device according to claim 1, further comprising a biasing circuit configured to separately bias the first polysilicon region and the second polysilicon region.

4. The device according to claim 1, further comprising a metallization that electrically connects the second polysilicon region and said storage region.

5. The device according to claim 1, wherein the at least one pixel further comprises a photosensitive zone, a read node comprising said storage region, and at least one transfer transistor configured to transfer said charge accumulated in the photosensitive zone to the read node, wherein the first polysilicon region forms a transfer gate for said transfer transistor.

6. The device according to claim 1, wherein said trench forms a capacitive isolation trench delineating the periphery of the pixel, and wherein said second electrode of the capacitor being connected to a read node by way of metal tracks.

7. The device according to claim 1, wherein said stack is surmounted by a region of insulator.

8. The device according to claim 1, wherein the device is a component of a smart mobile telephone.

9. The device according to claim 1, wherein the device is a component of a digital camera.

10. The device according to claim 1, wherein stack within said trench further includes a third polysilicon region, wherein the third and second polysilicon regions within the stack are insulated from each other by a further layer of insulating material.

11. An integrated circuit, comprising:
a substrate;
a trench extending into the substrate;
an insulator coating said trench;
a stack within said trench including a first polysilicon region and a second polysilicon region, wherein the first and second polysilicon regions within the stack are insulated from each other by a layer of insulating material; and
a capacitor having a first electrode formed by the second polysilicon region, a dielectric formed by the layer of insulating material, and a second electrode within the substrate.

12. The circuit according to claim 11, further comprising a metallization that electrically connects the second polysilicon region to the substrate.

13. The circuit according to claim 11, further comprising a biasing circuit configured to separately bias the first polysilicon region and the second polysilicon region.

14. The circuit according to claim 11, comprising a vertical transistor having a gate electrode formed by the first polysilicon region.

15. The circuit according to claim 11, wherein said trench peripherally surrounds a region of the substrate.

16. The circuit according to claim 11, wherein said stack is surmounted by a region of insulator.

17. The circuit according to claim 11, wherein the circuit is a component of an imaging pixel.

18. The circuit according to claim 17, wherein the imaging pixel is a component of a camera within a mobile telephone.

19. The circuit according to claim 17, wherein the imaging pixel is a component of a digital camera.

20. The circuit according to claim 11, wherein stack within said trench further includes a third polysilicon region, wherein the third and second polysilicon regions within the stack are insulated from each other by a further layer of insulating material.

21. The circuit according to claim 20, comprising a further capacitor having a first electrode formed by the third polysilicon region, a dielectric formed by the layer of insulating material, and a second electrode within the substrate.
